(19) United States
(12) Patent Application Publication
(10) Pub. No.: US 2026/0096054 A1
(43) Pub. Date: Apr. 2, 2026

(54) PIEZOELECTRIC FLUTTER COOLING SYSTEM

(71) Applicant: Intel Corporation, Santa Clara, CA (US)

(72) Inventors: Shih Wei Nien, Taipei (TW); Pei yang Sung, Taichung City (TW); Chun-Ting Liu, Taipei City (TW); Chung-Hsun Weng, Taipei (TW); Ritu Bawa, Bangalore (IN); Srinivasarao Konakalla, Bangalore (IN); Samarth Alva, Bangalore (IN); Satyajit Siddharay Kamat, Bangalore (IN); Arnab Sen, Whitefield (IN); Krishnendu Saha, Bangalore (IN); Prakash Kurma Raju, Bangalore (IN)

(73) Assignee: Intel Corporation, Santa Clara, CA (US)

(21) Appl. No.: 18/900,689

(22) Filed: Sep. 28, 2024

(51) Int. Cl. H05K 7/20; H10N 30/20

(52) U.S. Cl. CPC H05K 7/20209; H05K 7/20254; H05K 7/20336; H05K 7/20409; H10N 30/204

(57) ABSTRACT

Devices and systems for cooling using piezoelectricity are disclosed herein. In one example, a device includes a heat pipe, one or more fins thermally coupled to a first end of the heat pipe, where the fins extend laterally from the heat pipe, and one or more piezoelectric structures coupled to the fins.

### BACKGROUND

Active cooling and passive cooling are two different approaches for managing heat in electronic devices. Active cooling is typically used in high performance, power-intensive systems, while passive cooling is often used in low power, energy-efficient systems. In some cases, however, a system's design and cooling requirements may fall somewhere in the middle of the traditional use cases of active and passive cooling, where active cooling solutions are overkill but passive cooling solutions are insufficient.

### BRIEF DESCRIPTION OF THE DRAWINGS

FIGS. 1A-B illustrate an example of a piezoelectric flutter cooling system.

FIGS. 2A-C illustrate examples of piezo fins with varying shapes and geometries.

FIGS. 3A-B illustrate an example of a chassis for housing a system with a piezoelectric flutter cooling solution.

FIG. 4 illustrates an example of a chassis with a piezoelectric flutter cooling system housed inside.

FIGS. 5A-C illustrate an example of an electromagnetic flap cooling system.

FIGS. 6A-C illustrate an example of the flapping movement of an electromagnetic flap cooling system.

FIG. 7 illustrates a signal timing diagram of the drive signals for the first coil array in each set of coils.

FIG. 8 illustrates a signal timing diagram of the drive signals for coil arrays from the same set of coils.

FIG. 9 illustrates an example of a laptop computer with an electromagnetic flap cooling system integrated underneath the keyboard.

FIGS. 10A-B illustrate an array of flexible electromagnetic actuators arranged in series.

FIGS. 11A-B illustrate an example of an electromagnetic flapping system on a membrane with serrations for noise reduction.

FIG. 12 illustrates a cross-section side view of an integrated circuit device assembly in accordance with certain embodiments.

FIG. 13 illustrates a block diagram of an example electrical device in accordance with certain embodiments.

### DETAILED DESCRIPTION

Active cooling and passive cooling are two different approaches for managing heat in electronic devices (e.g., computers, laptops, tablets, smartphones). Active cooling is typically used in high performance, power-intensive systems, while passive cooling is often used in low power, energy-efficient systems.

In particular, active cooling uses external power and moving parts, such as fans or liquid cooling pumps, to dissipate heat. Active cooling is generally more efficient than passive cooling and can dissipate higher thermal loads, but active cooling tends to be noisy due to fans and other moving parts, requires power to operate which increases a system's overall energy consumption, and has a larger form factor that consumes more space in a system and increases its weight.

Passive cooling relies on heat dissipation through physical materials and natural processes (e.g., conduction, convection) using components such as heat sinks, heat spreaders, heat pipes, and vapor chambers. While passive cooling is less efficient than active cooling, passive cooling is more energy efficient since no power is required, silent due to the lack of moving parts, and generally has a smaller (and lighter) form factor.

In some cases, however, a system's design and cooling requirements may fall somewhere in the middle of traditional use cases of active and passive cooling, where active cooling solutions are overkill but passive cooling solutions are insufficient.

Accordingly, this disclosure presents embodiments of a piezoelectric flutter cooling system, and an electromagnetic flap cooling system, to address the shortcomings of existing active and passive cooling systems.

### Piezoelectric Flutter Cooling System

Most fanless laptops available today are built on lower-power hardware platforms compared to actively cooled systems. The limit of where fanless designs are possible is somewhere below 15 watts (W) of thermal design power (TDP) (e.g., the maximum amount of heat generated by a system that its cooling solution is required to dissipate). Once more power is needed, a fan is needed, which makes the system noisier and also increases its weight.

In particular, while passive cooling solutions have no moving parts and generate no noise, they are only suitable for lower power devices. On the other hand, while active cooling solutions are suitable for higher power devices, they are bulky and very noisy (e.g., due to fans and other moving parts), and as a result, systems that rely on active cooling tend to be larger and heavier. Active cooling solutions are also higher maintenance, as fan blades and other moving parts inevitably collect dust and debris, which requires them to be cleaned regularly.

Accordingly, this disclosure presents embodiments of a piezoelectric flutter cooling system, which uses piezoelectricity to enhance heat dissipation and airflow rather than using noisy fans and inefficient passive cooling solutions. In particular, piezoelectricity is used to induce fluttering or vibration in hot metal components, which enhances heat dissipation and airflow and helps cool system components that run hot. The flutter cooling system provides better cooling performance than traditional passive cooling solutions, while generating very little noise, particularly in comparison to actively-cooled thermal solutions with noisy fans.

The described embodiments may provide various advantages. For example, the piezoelectric flutter cooling solution increases cooling performance while maintaining a fanless design, which results in a better user experience, as it is much quieter and has a smaller form factor (e.g., thin, lightweight) than active fan-based cooling solutions, and it provides better cooling performance than traditional passive cooling solutions.

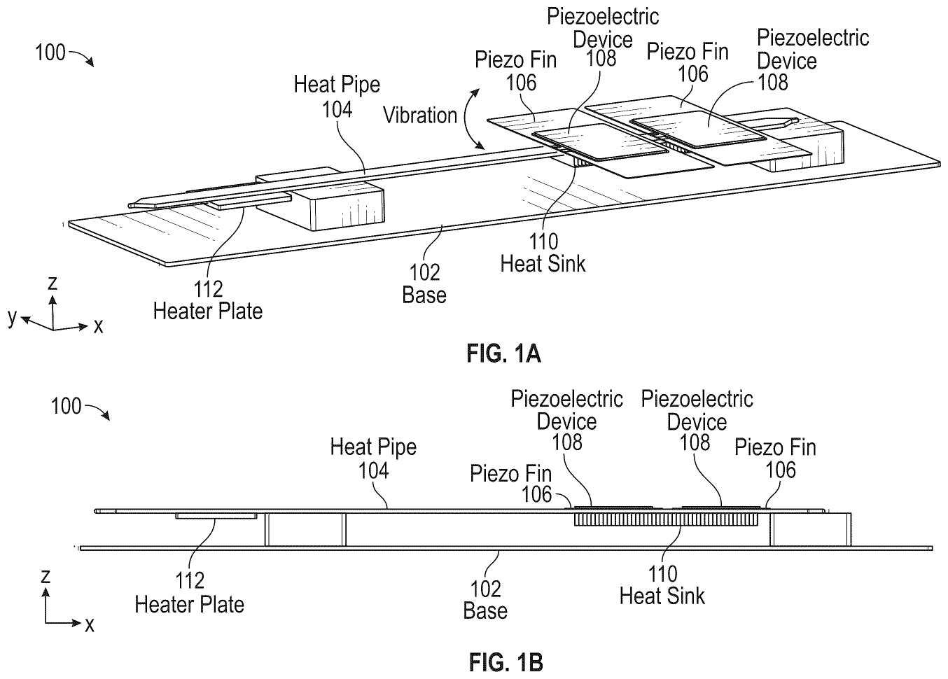

FIGS. 1A-B illustrate an example of a piezoelectric flutter cooling system 100. In the illustrated embodiment, the flutter cooling system 100 uses piezoelectricity to induce vibration, or fluttering, in passive cooling components, which enhances heat dissipation efficiency and airflow for improved cooling performance.

In the illustrated embodiment, the flutter cooling system 100 includes a heat pipe 104 with multiple piezo fins 106 (and associated piezoelectric devices 108) thermally coupled above the heat pipe 104 on one end, a heat sink 110 thermally coupled below the heat pipe 104 on the same end, and a heater plate 112 thermally coupled below the heat pipe 104 on the opposite end. The piezo fins 106 extend laterally from the heat pipe 104 (e.g., substantially perpendicular to the heat pipe 104). Moreover, a piezoelectric device 108 is attached on top of each piezo fin 106. In some embodiments, the respective components may be welded to the heat pipe 104. Moreover, the heat pipe 104 (and associated components) are mounted on a base structure 102.

The piezo fins 106 may be thermally conductive structures, such as thin copper (Cu) plates. The piezoelectric (PE) devices 108 may be structures made of a piezoelectric (PE) material—which is a material that exhibits the piezoelectric effect (e.g., as described further below)—such as thin layers, sheets, or plates of piezoelectric material. The heater plate 112 may be a thermally and/or electrically conductive structure, such as a (e.g., square or rectangular) copper (Cu) block or plate.

Moreover, a power supply (not shown) may be electrically coupled to the PE devices 108, which enables a voltage to be applied to the PE devices 108 to induce the inverse piezoelectric effect.

Further, a heat source (not shown), which may also be referred to as a heater, may be thermally coupled to the bottom side of the heater plate 112. In some embodiments, the heat source may include any electronic component that relies on the PE cooling system 100 for heat dissipation and cooling (e.g., a system-on-a-chip (SoC), processor, etc.).

In this manner, when the heat source generates heat, the heat may be transferred from the heat source to the heater plate 112, and then from the heater plate 112 to the adjacent end of the heat pipe 104. The heat may then be routed through the heat pipe 104 from one end to the other, and then to the PE fins 106 and heat sink 110 on that end of the heat pipe 104, where the heat is eventually dissipated into the surrounding environment, thus cooling the heat source.

At the same time, however, a voltage is applied across the PE devices 108 (e.g., via the power supply or power source), which induces micro-vibrations, or “flutters,” in the PE devices 108 due to the (reverse) piezoelectric effect. The frequency and amplitude of the micro-vibrations can be adjusted based on the applied input voltage. Moreover, as the PE devices 108 vibrate up and down, the piezo fins 106 also vibrate, which enhances heat dissipation efficiency and airflow. In particular, the micro-vibrations in the piezo fins 106 generate airflow, and the micro-vibrations also increase the heat transfer capacity of the piezo fins 106 and the heat sink 110, which enables those components to dissipate heat more efficiently.

The piezoelectric effect is a phenomenon where certain materials generate an electric charge in response to applied mechanical stress (and vice versa). For example, when mechanical stress or pressure is applied to a piezoelectric material, the internal distribution of electric charges becomes imbalanced, which produces an electric field or voltage across the surfaces of the material. This is referred to as the direct piezoelectric effect. Conversely, if an electric field is applied to a piezoelectric material, it undergoes a change in structure that causes physical movement or deformation (e.g., expanding or contracting, vibrating). This is referred to as the reverse piezoelectric effect.

In the illustrated embodiment, flutter cooling system 100 leverages the reverse piezoelectric effect to induce vibrations or fluttering in the piezo fins 106 by applying an electric field to the PE devices 108.

The piezoelectric effect arises from the unique crystal structure of certain materials that are non-centrosymmetric, which refers to materials with no center of symmetry or inversion symmetry. In this disclosure, a piezoelectric material may refer to any material that exhibits the piezoelectric effect. Examples of piezoelectric materials include, without limitation: quartz (SiO₂); tourmaline; ceramics such as lead zirconate titanate (PZT) (Pb[ZrₓTi₁₋ₓ]O₃) and barium titanate (BaTiO₃); polymers such as polyvinylidene fluoride (PVDF) (C₂H₂F₂); semiconductors such as zinc oxide (ZnO), gallium nitride (GaN); and certain biological materials (e.g., bone, collagen). Thus, in various embodiments, a piezoelectric material may include elements such as lead, barium, zirconium, titanium, gallium, zinc, silicon, fluorine, oxygen, nitrogen, carbon, and/or hydrogen, including, without limitation, any of the following combinations: silicon and oxygen; barium, titanium, and oxygen; zinc and oxygen; gallium and nitrogen; lead, zirconium, titanium, oxygen; or carbon, hydrogen, and fluorine.

A heat pipe 104 may refer to a tubular enclosure that uses principles of evaporation and condensation to efficiently transfer and dissipate heat from one point to another. For example, a heat pipe 104 may include a hollow tubular enclosure made of conductive materials (e.g., copper or aluminum) that contains a wick lining on its inner walls and a working fluid (e.g., water, ammonia, acetone, methanol). When the hot end of the heat pipe 104 is exposed to heat, the working fluid inside the heat pipe 104 absorbs the heat and evaporates into vapor. The vapor then flows through the hollow cavity to the cool end of the heat pipe 104. At the cool end, the vapor cools and condenses back into liquid, thus releasing the heat (e.g., into the surrounding environment and/or a cooling medium). The condensed liquid is then drawn back to the hot end (e.g., through the capillary action of the wick) and the cycle continues.

In various embodiments, any of the passive cooling components in system 100 may be replaced or supplemented with other passive (or active) cooling embodiments. In some embodiments, for example, the heat pipe 104 may be replaced or supplemented with one or more other heat transfer devices (e.g., heat pipes, vapor chambers, thermal spreaders, fins, heat sinks, heat exchangers, thermosyphons, radiators, etc.).

In this disclosure, components that are “thermally coupled” may be directly or indirectly coupled in a manner that facilitates the transfer of thermal energy (e.g., heat).

Embodiments of PE cooling solutions are described in further detail in connection with other figures. The concepts described above with respect to system 100, including the modifications and variations thereof, also apply to the other embodiments of PE cooling solutions described throughout this disclosure (and vice versa).

Table 1 shows thermal test results for an example flutter cooling solution using four test cases. Case 1 is the baseline with the piezo cooler disabled, and cases 2-4 enable the piezo cooler under different frequency/amplitude configurations, where the heater provides 5 watts of power for each test case. Based on these results, case 3 provides the best configuration. The heater's junction temperature improves +5.5%, and the piezo fin temperatures improve more than +11˜%. In case 4, the amplitude was halved, and the cooling performance decreased. The optimal frequency value for the piezoelectricity is dependent on the size and shape of the piezo fins, which can be determined through experimental testing. Moreover, the optimal amplitude depends on the cooling requirements, which will affect the noise level and the base plane of the vibration.

TABLE 1
Thermal Validation Results for Flutter Cooling Solution

| | | Test 1 | | | | | | |
|---|---|---|---|---|---|---|---|---|
| | | (baseline) | Test 2 | | Test 3 | | Test 4 | |
| Piezoelectricity | Frequency | Off | 130 | Hz | 110 | Hz | 110 | Hz |
| | Amplitude | Off | +95 V/−0 V | | +95 V/−0 V | | +50 V/−0 V | |
| Heater | Power | 5.0 Watts | 5.0 | Watts | 5.0 | Watts | 5.0 | Watts |

Thermal tests @ 26° C. ambient temperature

| Heater Junction Temperature | 96.0 | 91.6 | 90.7 | 96.5 |
|---|---|---|---|---|
| | | (−4.6%) | (−5.5%) | (+0.5%) |
| Fin 1 Temperature | 56.9 | 55.6 | 50.2 | 56.5 |
| | | (−2.3%) | (−11.8%) | (−0.7%) |
| Fin 2 Temperature | 54.8 | 52.7 | 46.6 | 52.0 |

| | | |
|---|---|---|
| (−3.8%) | (−15.0%) | (−5.1%) |

Table 2 shows thermal test results when the PE flutter cooling solution configured on and off under 5 W and 10 W of power, respectively. When the PE cooling solution is enabled, the heater temperature is reduced by 3.4% under the 10 W workload and by more than 5% under the 5 W workload. Cooling performance can be improved even further by optimizing the design and configuration of the cooling solution (e.g., number of fins, fin geometry, amplitude/frequency configurations, etc.) for a particular system.

TABLE 2
Thermal Performance Tests of Flutter Cooling Solution

| | | Temperature (° C.) | | | |
|---|---|---|---|---|---|
| Power | | | Heat Pipe | Piezo Fin | Piezo Fin |
| (watts (W)) | Piezo | Heater | (near heater) | (middle) | (ends) |
| 5 W | OFF | 110.98 | 66.92 | 65.8 | 55.95 |
| | ON | 107.24 | 61.44 | 61.39 | 45.92 |
| | ΔT | 3.74 | 5.48 | 4.41 | 10.03 |
| | | (−3.4%) | (−8.2%) | (−6.7%) | (−17.9%) |
| 10 W | OFF | 71.85 | 48.55 | 48.47 | 44 |
| | ON | 68.14 | 44.84 | 44.25 | 36.71 |
| | ΔT | 3.71 | 3.71 | 4.22 | 7.29 |
| | | (−5.2%) | (−7.6%) | (−8.7%) | (−16.6%) |

Moreover, compared to active cooling, the PE flutter cooling solution consumes very little power. For example, an active cooling solution with a fan typically requires around 4 watts to drive the fan to rotate. By comparison, the PE flutter cooling solution only requires 0.31 watts to drive vibrations in three piezo fins.

Further, the PE flutter cooling solution is very quiet and generates very little noise. For example, with respect to a PE flutter cooling system driven at a frequency of 70 hertz (Hz) and an amplitude of +−55 volts (V), the noise level may only increase by around 1.7 decibels (dB) with the PE cooler powered on versus off.

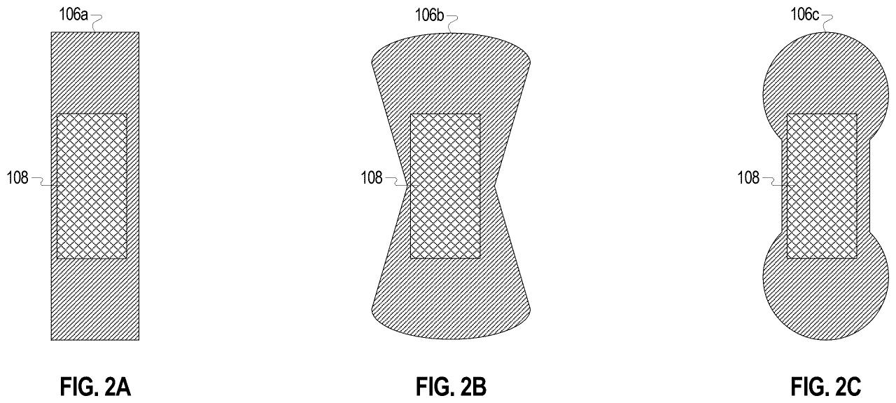

FIGS. 2A-C illustrate examples of piezo fins 106a-c with varying shapes and geometries. The size and number of piezo fins 106a-c in a system can vary depending on the requirements, including cooling efficiency and space constraints (e.g., available space in a system to accommodate piezo fins 106a-c). Moreover, the shape and geometries of the piezo fins 106a-c can also vary in different embodiments, as different fin geometries will affect the strength of the airflow and heat dissipation created by the vibrations of the piezo fins 106a-c. In various embodiments, for example, the fins 106 may have a rectangular shape, circular shape, curved shape, polygonal shape, symmetric shape, asymmetric shape, irregular shape, etc., with varying dimensions, surface area, thicknesses, and so forth.

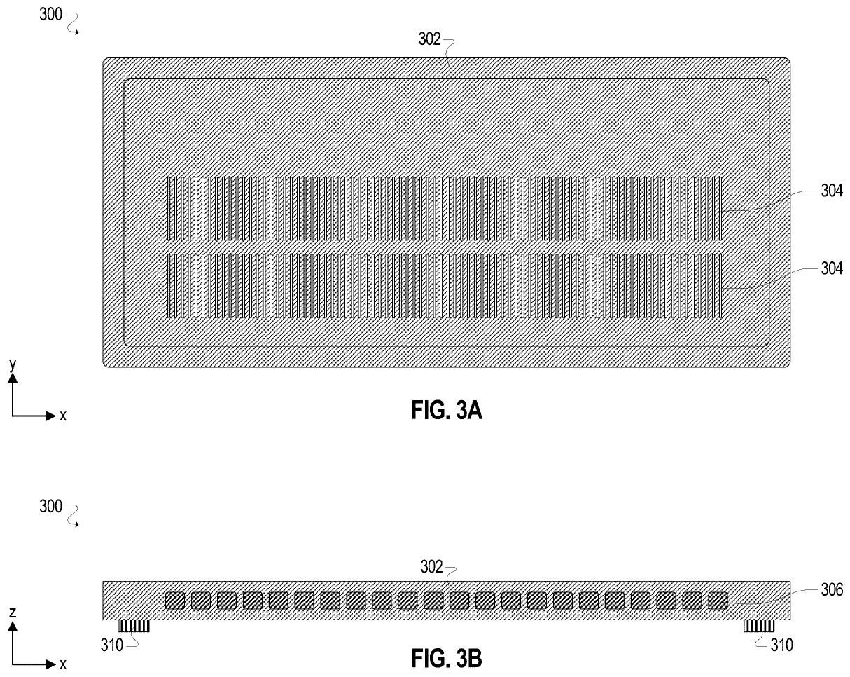

FIGS. 3A-B illustrate an example of a chassis 300 for housing a system with a piezoelectric flutter cooling solution. In particular, FIG. 3A shows a plan (x-y plane) view of the chassis 300, and FIG. 3B shows a side (x-z plane) view of the chassis 300. In the illustrated embodiment, chassis 300 is designed as a fully-enclosed chassis assembly with a body 302 and a removable top cover or lid (not shown). The body 302 includes bottom vents 304 and side vents 306, along with mechanical feet or foot stands 310. The lid of the chassis 300 can be removed, and a system with an associated PE flutter cooling module can be placed and/or assembled inside the chassis body 302, and afterwards the lid can be closed. Moreover, the vents 304, 306 can be opened or closed in different configurations to optimize cooling performance (e.g., open all vents 304, 306, close half of bottom vents 304 on one side, close half of side vents 306 on one side, or close half of bottom vents 304 on one side and close half of side vents 306 on the other side).

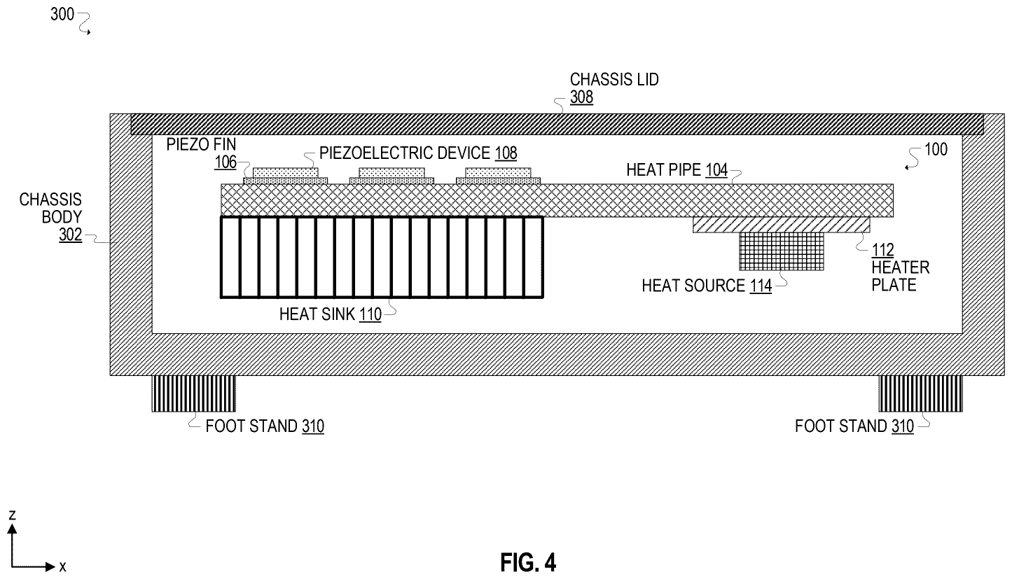

FIG. 4 illustrates a cross-section (x-z plane) view of a chassis 300 with a piezoelectric flutter cooling system 100 housed inside. In the illustrated embodiment, the chassis 300 includes a body 302 with foot stands 310 and a removable lid 308. Moreover, a PE flutter cooling system 100 is housed inside the chassis 300, which includes a heat pipe 104, a heat sink 110, piezo fins 106 with associated piezoelectric (PE) devices 108, a heater plate 112, and a heat source 114. Moreover, a power supply (not shown) may be electrically coupled to the PE devices 108, which enables a voltage to be applied to the PE devices 108 to induce the inverse piezoelectric effect.

The heat source 114 is thermally coupled to the heater plate 112, and in turn, to the adjacent end of the heat pipe 104 through the heater plate 112. The heat source 114 may include any electronic component that relies on the PE cooling system 100 for heat dissipation and cooling, such as an integrated circuit (IC) (e.g., an IC die or package on a circuit board with processing circuitry, memory circuitry, storage circuitry, communication circuitry). In particular, the IC 114 may include one or more IC dies (e.g., on a package substrate) containing any type or combination of integrated circuitry, including, without limitation, one or more systems-on-a-chip (SoCs), microprocessors (e.g., central processing units (CPUs), graphics processing units (GPUs), vision processing units (VPUs), neural processing units (NPUs), other XPUs), field-programmable gate arrays (FPGAs), application-specific integrated circuits (ASICs), network interface controllers (NICs), persistent storage devices, input/output (I/O) devices and controllers, memory devices and controllers, and/or voltage regulators, among other components.

In the illustrated embodiment, heat generated by the heat source 114 is transferred to the heater plate 112 and then to the heat pipe 104, and then to the piezoelectric fins 106 and the heat sink 110. Moreover, a voltage is applied across the piezoelectric (PE) devices 108 (e.g., by a power supply), which causes the PE devices 108 to vibrate due to the PE effect. In turn, the vibrations in the PE devices 108 cause the piezo fins 106 to vibrate, which enhances heat dissipation efficiency the fins 106 and the heat sink 110. In this manner, the heat generated by the heat source 114 is transferred to the other end of the heat pipe 104 and then dissipated, thus cooling the heat source 114.

### Electromagnetic Flap Cooling System

This disclosure also presents embodiments of an electromagnetic (EM) flap cooling system. In particular, the EM flap cooling system uses electromagnetic induction to induce a coordinated flapping movement in a series of flexible flap actuators, with carefully orchestrated synchronization among the actuators, which causes them to flap in sequence to produce air movement or airflow.

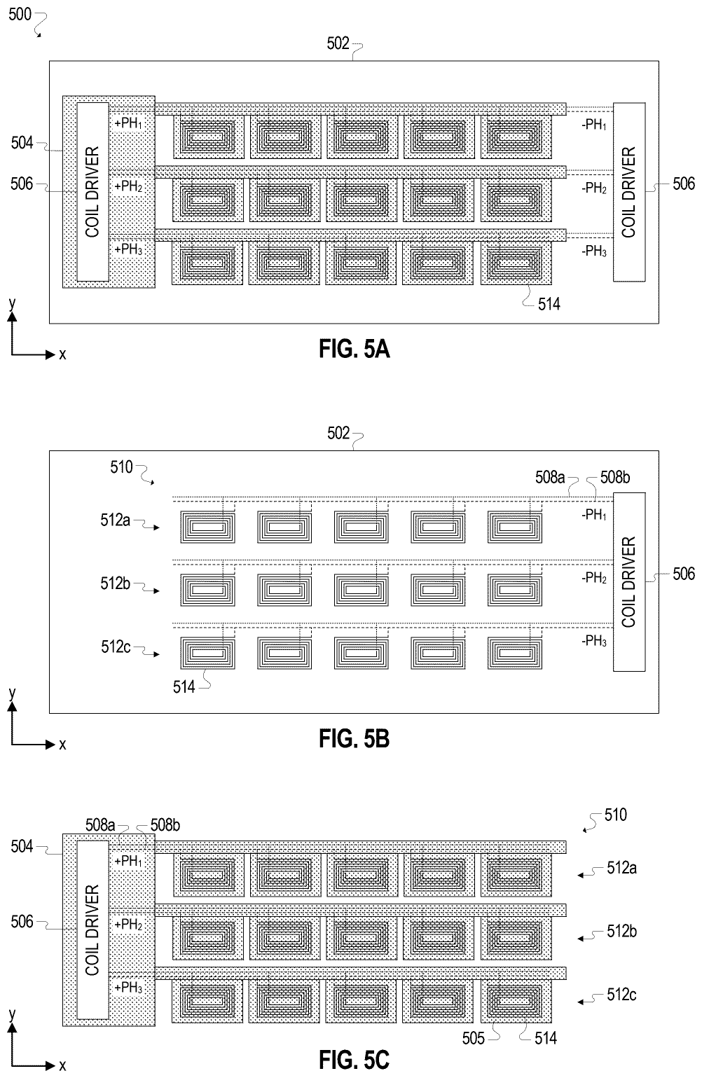

FIGS. 5A-C illustrate plan (x-y plane) views of an example electromagnetic (EM) flap cooling system 500. In particular, FIG. 5A illustrates the assembled system 500, which includes two substrates 502, 504 with two sets of conductive coils 510 stacked one on top of the other, while FIGS. 5B and 5C illustrate the respective substrates 502, 504 in isolation. Each substrate 502, 504 includes a set 510 of conductive coils 514 arranged into three rows 512a-c, along with an associated coil driver 506, which is connected to the respective coils 514 via signal traces 508a,b.

The top substrate 504 may be a flexible substrate or planar surface, such as a flexible printed circuit (FPC). In some embodiments, for example, the top substrate 504 may be made of Kapton FPC material. Moreover, the top substrate 504 is patterned with rows of flaps 505, with a corresponding coil 514 formed on each flap 505.

The bottom substrate 502 can be any type of substrate or planar surface, as it is not required to be flexible or permit movement. In some embodiments, for example, the bottom substrate 502 may be a printed circuit board (PCB), such as the backside of a keyboard PCB or another existing PCB in a system to conserve space.

The conductive coils 514 may be formed with conductive traces, such as copper (Cu) traces.

The EM flap cooling system 500 is built with two sets of coils 510 on the top and bottom substrates 502, 504, which are stacked one on top of the other, such that the coils 514 on the respective substrates 502, 504 are aligned/overlapping. Alternatively, in some embodiments, the set of coils 510 on the bottom substrate 502 may be replaced with a thin permanent magnet sheet.

The coil drivers 506 control the drive signals applied to each row of coils 512a-c on the respective substrates 502, 504. In this manner, the phases of the drive signals can be controlled to induce electromagnetic movement in the flap actuators 505, causing them to flap in synchronization to produce air movement or airflow.

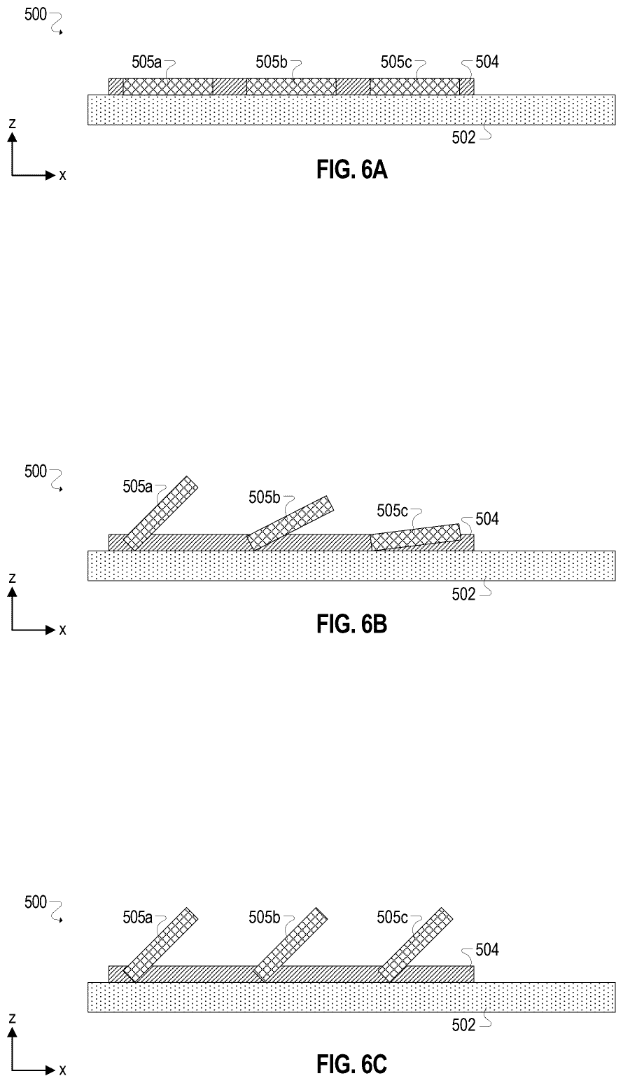

FIGS. 6A-C illustrate an example of the flapping movement of the electromagnetic (EM) flap cooling system 500. In particular, FIGS. 6A, 6B, and 6C depict an array of three flap actuators 505a-c in different actuation or flap states. In FIG. 6A, the flaps 505a-c are unactuated and are all flat and motionless. In FIG. 6B, the flaps 505a-c are actuated and in different flapping positions. In FIG. 6C, the flaps 505a-c are actuated and in the maximum flapping position.

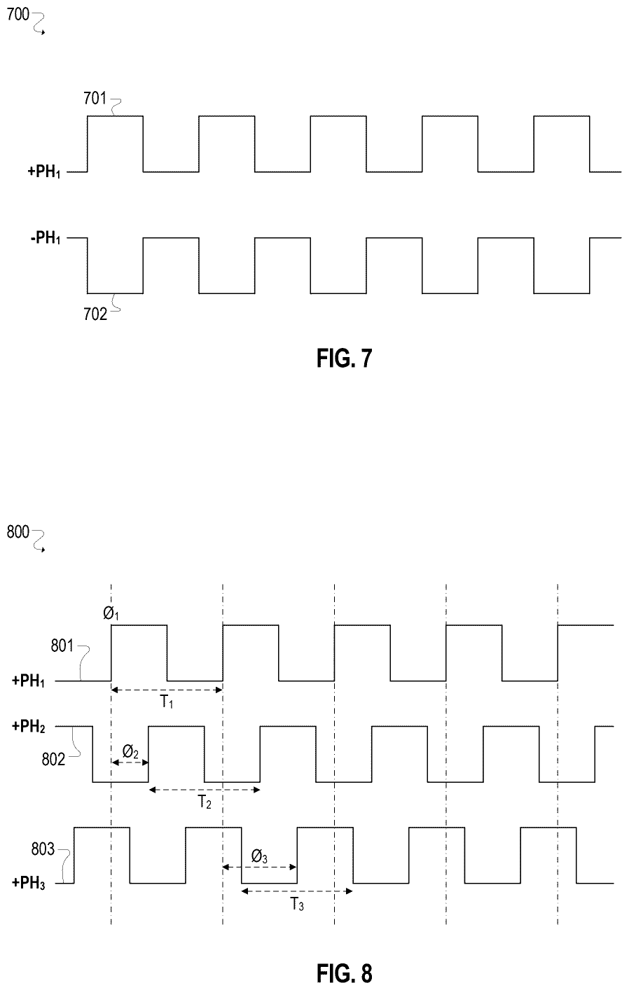

To achieve this flapping movement, the coil drivers 506 are synchronized such that the drive signal (+PH₁) for the first row of coils 512a in the flex substrate 504 is out of phase (−PH₁) with respect to the first row of coils 512a in the base substrate 502 (as shown in FIG. 7). In this manner, magnetic fields in the coils 514 either oppose or attract each other, thus creating flapping motion in the flap actuators 505. The same is true for the drive signals for the second and third rows of coils (PH₂, PH₃). This is depicted in FIG. 7, which shows a signal timing diagram 700 of the drive signals 701, 702 (+PH₁, −PH₁) for the first array or row of coils 512a in each set of coils 510 on the respective substrates 502, 504.

To produce directional flow in a chassis using these row actuators 512a-c, phase differences between the drive signals for each row 512a-c (PH₁, PH₂, PH₃) can be introduced (as shown in FIG. 8). For example, by controlling and tuning phase difference (Ø₁, Ø₂, Ø₃), duty cycle, and period of drive signals (T₁, T₂, T₃), unidirectional flow can be created. This phase signal modulation is performed by a microcontroller along with the coil driver circuitry 506. This is depicted in FIG. 8, which shows a signal timing diagram 800 of the drive signals 801, 802, 803 (+PH₁, +PH₂, +PH₃) for each array or row of coils 514 on the flexible actuator substrate 504.

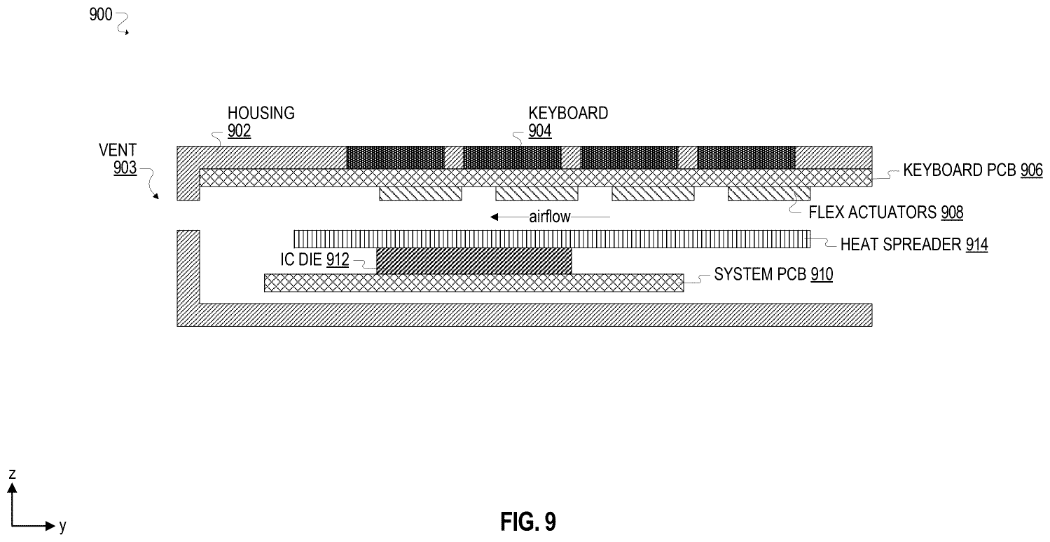

FIG. 9 illustrates a cross-section (y-z plane) view of a laptop computer 900 with an electromagnetic flap cooling system integrated underneath the keyboard. In the illustrated embodiment, the laptop 900 includes a laptop housing 902 with a rear vent 903 and a keyboard 904 on the top surface. In some embodiments, the laptop housing 902 may include a top keyboard cover (e.g., C cover) and a bottom cover (e.g., D cover). Inside the housing 902, the laptop 900 includes a keyboard printed circuit board (PCB) 906 located below the keyboard 904. The keyboard 904 is attached to the frontside of the keyboard PCB 906, and an array of flex actuators 908 attached to the backside of the keyboard PCB 906. The laptop 900 also includes a system PCB 910 inside the housing 902, along with one or more integrated circuit (IC) dies 912 attached above the system PCB 910, and a heat spreader 914 attached above the IC die(s) 912.

In this manner, the arrays of flexible EM actuators 908 are integrated on the keyboard PCB 906 (e.g., the keyboard backplate) to provide improved passive cooling. For example, as described above, the flexible EM actuators 908 are constructed of a thin, flexible material, and they are actuated synchronously to create a wave of moving air particles. In the illustrated embodiment, for example, the EM actuators 908 can be actuated synchronously to displace air onto the heat spreader 914 in the core region. In other embodiments, the actuators 908 may be integrated in other suitable locations, such as near the forehead region or on either side of the keyboard 904. Moreover, the flexible actuators 908 can have a thin FPC-type footprint, which makes this a viable and affordable solution for integration into a system design.

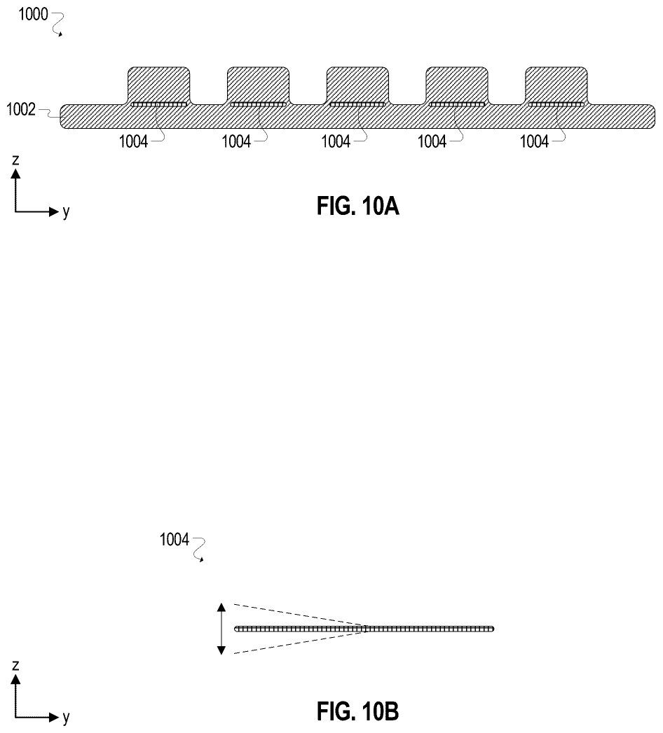

FIGS. 10A-B illustrate an array 1000 of flexible electromagnetic (EM) actuators 1004 arranged in series in a substrate 1002. In particular, FIG. 10A illustrates a side view (y-z plane) of the EM actuators 1004 arranged in series in a substrate/membrane 1002, and FIG. 10B illustrates a magnified side view (y-z plane) of the flapping movement of a single EM actuator 1004. The EM flap actuators 1004 are designed to be operated in either a single array or multiple arrays of actuators 1004. For each array, multiple flap actuators 1004 are attached, and they are designed to flap in the vertical direction when actuated (e.g., as shown in FIG. 10B). In particular, the flap actuators 1004 have actuated and unactuated states. In an actuated state, an actuator 1004 will flap (e.g., as shown in 10B), whereas in an unactuated state, the actuator 1004 will be flat (e.g., as shown in FIG. 10A). In this manner, the actuator arrays can be operated synchronously to achieve uniform air flow.

The number of actuator arrays that can be accommodated depends on the available area inside the system. Based on typical passive designs floor plans, the space available in the z direction may be anywhere from 1.5 to 3 mm.

Moreover, the displacement and frequency can be controlled as per system design requirements. In some cases, the number of cycles may be targeted to operate at extremely high frequencies (e.g., over 20 kilohertz (kHz)) to achieve higher air flow with low acoustics.

The airflow estimation for a single array of actuators with five flaps is provided in Table 3. With respect to the airflow estimation for 2 mm flapper displacement, the open flow displaces ˜0.64 cubic feet per minute (CFM) at a maximum pressure head of 7 mm of H₂O. The volume flowrate values are tabulated in Table 3 for different flapper displacement values.

TABLE 3
Airflow estimation for a single array of actuators with 5 flaps

| | Actuation | | Volume | | | Open flow |
|---|---|---|---|---|---|---|
| Actuator | Depth | Frequency | Displacement | Flow | | CFM for 5 |
| Area (mm²) | (mm) | (Hz) | (mm³) | (mm³/sec) | CFM/flap | flaps |
| 15 | 1.8 | 20000 | 27 | 540000 | 0.11 | 0.57 |
| 15 | 2 | 20000 | 30 | 600000 | 0.13 | 0.64 |
| 15 | 3 | 20000 | 45 | 900000 | 0.19 | 0.95 |

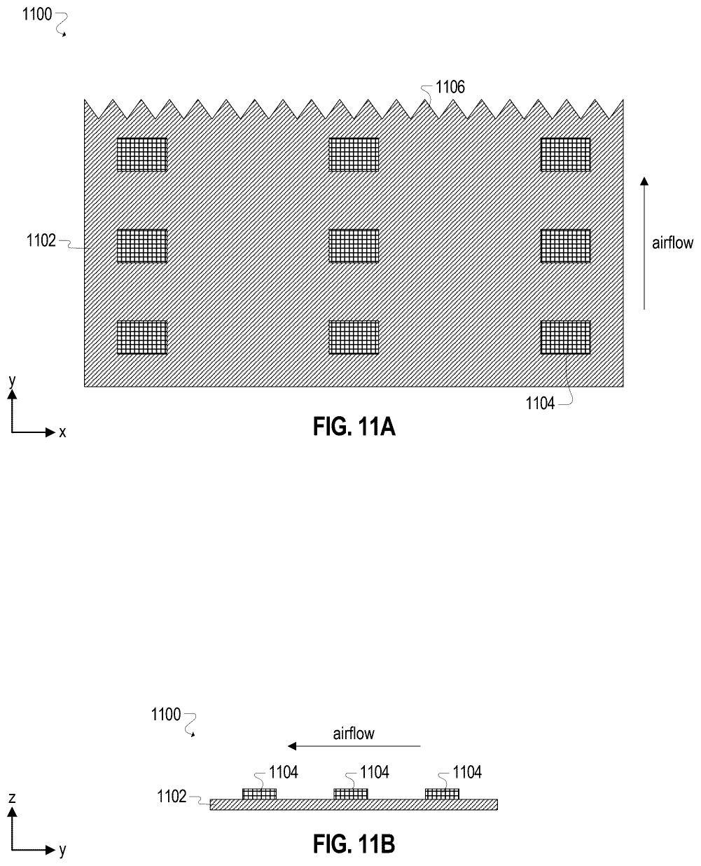

FIGS. 11A-B illustrate an example of an electromagnetic flapping system 1100 on a membrane 1102 with serrations 1106 for noise reduction. In particular, FIG. 11A illustrates a plan (x-y plane) view of the system 1100, and FIG. 11B illustrates a side (y-z plane) view of the system 1100. In the illustrated embodiment, the EM flapping system 1100 includes multiple arrays of flap actuators 1104 on a flapping membrane 1102 with serrations 1106 to mimic bird wing motion for reduced noise. The flap actuators 1104 are arranged into three arrays with three actuators 1104 per array. Moreover, the serrations 1106 in the flapping membrane 1102 are biological-inspired features to reduce noise, or alternatively, improve airflow without generating more noise.

In particular, since the system 1100 relies on a flapping mechanism, biological-inspired features can be introduced that help certain birds maintain silent flight, such as owls and bats. In particular, owls have serrations at their trailing edge which enables them to maintain silent flight. Accordingly, in the illustrated embodiment, system 1100 has serrations 1106 on the trailing edge of the membrane 1102.

Trailing edge serrations facilitate the departure of flow turbulence from the trailing edge at an angle relative to the mainstream flow. This results in the creation of trailing edge vortices that exit the surface at angles, causing interference with each other, ultimately leading to their elimination or degradation. Consequently, this mechanism allows for the generation of lower noise.

It is also observed that larger birds have two distinct wing areas along their span—a fixed part and a flapping part. The fixed portion acts like an airfoil, generating lift, while the flapping part is responsible for generating forward motion and additional lift. The motion of the wingtip is highly three-dimensional and not merely a simple flapping motion. These intricate wing movements can be replicated in a silicone or stretchable membrane by individually controlling the actuators.

### Example Embodiments

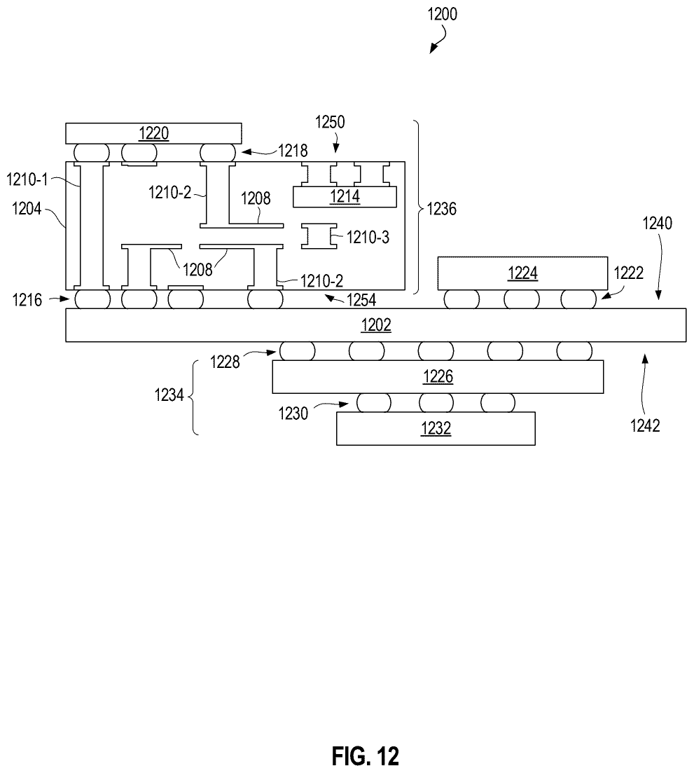

FIG. 12 is a cross-sectional side view of an integrated circuit device assembly 1200 that may include any of the embodiments disclosed herein. In some embodiments, for example, the integrated circuit device assembly 1200 may include any of the cooling systems disclosed herein (e.g., piezoelectric flutter cooling system, electromagnetic flap cooling system) around any of the IC components 1220, 1224, 1226, 1232 on the circuit board 1202.

In some embodiments, the integrated circuit device assembly 1200 may be a microelectronic assembly. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the microelectronic assemblies disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

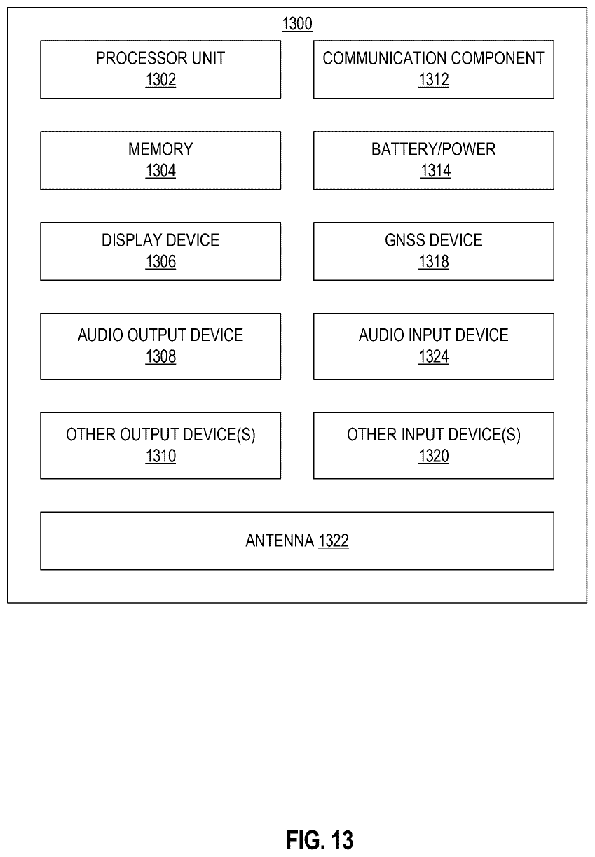

FIG. 13 is a block diagram of an example electrical device 1300 that may include one or more of the embodiments disclosed herein. In some embodiments, for example, the electrical device 1300 may include a piezoelectric flutter cooling system and/or an electromagnetic flap cooling system according to any of the embodiments disclosed herein.

A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards, mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include other output device(s) 1310 (or corresponding interface circuitry, as discussed above). Examples of the other output device(s) 1310 may include an audio codec, a video codec, a printer, a wired or wireless transmitter for providing information to other devices, or an additional storage device.

The electrical device 1300 may include other input device(s) 1320 (or corresponding interface circuitry, as discussed above). Examples of the other input device(s) 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform comprising dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a device, comprising: a heat pipe; one or more fins thermally coupled to a first end of the heat pipe, wherein the one or more fins extend laterally from the heat pipe; and one or more piezoelectric structures coupled to the one or more fins.

Example 2 includes the device of Example 1, wherein the one or more piezoelectric structures comprise a piezoelectric material.

Example 3 includes the device of Example 2, wherein the piezoelectric material comprises quartz, tourmaline, lead zirconate titanate, barium titanate, polyvinylidene fluoride, zinc oxide, or gallium nitride.

Example 4 includes the device of Example 2, wherein the piezoelectric material comprises: silicon and oxygen; barium, titanium, and oxygen; zinc and oxygen; gallium and nitrogen; lead, zirconium, titanium, oxygen; or carbon, hydrogen, and fluorine.

Example 5 includes the device of any of Examples 1-4, further comprising a power supply to apply a voltage to the one or more piezoelectric structures.

Example 6 includes the device of any of Examples 1-5, further comprising a heat sink coupled to the first end of the heat pipe, wherein the one or more fins are disposed above the heat pipe, and wherein the heat sink is disposed below the heat pipe.

Example 7 includes the device of any of Examples 1-6, further comprising a plate thermally coupled to a second end of the heat pipe, wherein the plate is to be thermally coupled to an electronic component.

Example 8 includes the device of Example 7, further comprising the electronic component, wherein the electronic component comprises processing circuitry, memory circuitry, storage circuitry, or communication circuitry.

Example 9 includes the device of any of Examples 1-8, wherein the one or more fins comprise a rectangular shape.

Example 10 includes the device of any of Examples 1-8, wherein the one or more fins comprise a curved shape.

Example 11 includes the device of any of Examples 1-10, wherein the one or more fins comprise a symmetric shape.

Example 12 includes a piezoelectric cooling device, comprising: a heat transfer device; one or more fins thermally coupled to a first end of the heat transfer device, wherein the one or more fins extend substantially perpendicular to the heat transfer device; one or more layers of piezoelectric material on the one or more fins; and a power supply to apply a voltage to the one or more layers of piezoelectric material.

Example 13 includes the piezoelectric cooling device of Example 12, wherein the heat transfer device comprises a heat pipe.

Example 14 includes the piezoelectric cooling device of any of Examples 12-13, further comprising a heat sink coupled to the first end of the heat transfer device, wherein the one or more fins are disposed above the heat transfer device, and wherein the heat sink is disposed below the heat transfer device.

Example 15 includes the piezoelectric cooling device of any of Examples 12-14, further comprising a heater plate thermally coupled to a second end of the heat transfer device, wherein the heater plate is to be thermally coupled to an electronic component.

Example 16 includes a system, comprising: a heat pipe; one or more fins thermally coupled to a first end of the heat pipe, wherein the one or more fins extend laterally from the heat pipe; one or more piezoelectric structures coupled to the one or more fins; and an integrated circuit thermally coupled to a second end of the heat pipe.

Example 17 includes the system of Example 16, further comprising a power supply to apply a voltage to the one or more piezoelectric structures.

Example 18 includes the system of any of Examples 16-17, further comprising a heater plate, wherein the integrated circuit is thermally coupled to the heater plate, and wherein the heater plate is thermally coupled to the second end of the heat pipe.

Example 19 includes the system of any of Examples 16-18, wherein the integrated circuit comprises a system-on-a-chip, a central processing unit, a graphics processing unit, a network interface controller, a storage device, a memory controller, or an input/output controller.

Example 20 includes the system of any of Examples 16-19, further comprising a circuit board, wherein the integrated circuit is coupled to the circuit board.

1. A device, comprising:
a heat pipe;
one or more fins thermally coupled to a first end of the heat pipe, wherein the one or more fins extend laterally from the heat pipe; and
one or more piezoelectric structures coupled to the one or more fins.

2. The device of claim 1, wherein the one or more piezoelectric structures comprise a piezoelectric material.

3. The device of claim 2, wherein the piezoelectric material comprises quartz, tourmaline, lead zirconate titanate, barium titanate, polyvinylidene fluoride, zinc oxide, or gallium nitride.

4. The device of claim 2, wherein the piezoelectric material comprises:
silicon and oxygen;
barium, titanium, and oxygen;
zinc and oxygen;
gallium and nitrogen;
lead, zirconium, titanium, oxygen; or
carbon, hydrogen, and fluorine.

5. The device of claim 1, further comprising a power supply to apply a voltage to the one or more piezoelectric structures.

6. The device of claim 1, further comprising a heat sink coupled to the first end of the heat pipe, wherein the one or more fins are disposed above the heat pipe, and wherein the heat sink is disposed below the heat pipe.

7. The device of claim 1, further comprising a plate thermally coupled to a second end of the heat pipe, wherein the plate is to be thermally coupled to an electronic component.

8. The device of claim 7, further comprising the electronic component, wherein the electronic component comprises processing circuitry, memory circuitry, storage circuitry, or communication circuitry.

9. The device of claim 1, wherein the one or more fins comprise a rectangular shape.

10. The device of claim 1, wherein the one or more fins comprise a curved shape.

11. The device of claim 1, wherein the one or more fins comprise a symmetric shape.

12. A piezoelectric cooling device, comprising:
a heat transfer device;
one or more fins thermally coupled to a first end of the heat transfer device, wherein the one or more fins extend substantially perpendicular to the heat transfer device;
one or more layers of piezoelectric material on the one or more fins; and
a power supply to apply a voltage to the one or more layers of piezoelectric material.

13. The piezoelectric cooling device of claim 12, wherein the heat transfer device comprises a heat pipe.

14. The piezoelectric cooling device of claim 12, further comprising a heat sink coupled to the first end of the heat transfer device, wherein the one or more fins are disposed above the heat transfer device, and wherein the heat sink is disposed below the heat transfer device.

15. The piezoelectric cooling device of claim 12, further comprising a heater plate thermally coupled to a second end of the heat transfer device, wherein the heater plate is to be thermally coupled to an electronic component.

16. A system, comprising:
a heat pipe;
one or more fins thermally coupled to a first end of the heat pipe, wherein the one or more fins extend laterally from the heat pipe;
one or more piezoelectric structures coupled to the one or more fins; and
an integrated circuit thermally coupled to a second end of the heat pipe.

17. The system of claim 16, further comprising a power supply to apply a voltage to the one or more piezoelectric structures.

18. The system of claim 16, further comprising a heater plate, wherein the integrated circuit is thermally coupled to the heater plate, and wherein the heater plate is thermally coupled to the second end of the heat pipe.

19. The system of claim 16, wherein the integrated circuit comprises a system-on-a-chip, a central processing unit, a graphics processing unit, a network interface controller, a storage device, a memory controller, or an input/output controller.

20. The system of claim 16, further comprising a circuit board, wherein the integrated circuit is coupled to the circuit board.
